(19) United States
(12) Patent Application Publication
(10) Pub. No.: US 2014/0267504 A1
(43) Pub. Date: Sep. 18, 2014

(54) PIEZOELECTRIC ELEMENT, LIQUID EJECTING HEAD, LIQUID EJECTING APPARATUS, ULTRASONIC TRANSDUCER, AND ULTRASONIC DEVICE

(71) Applicant: SEIKO EPSON CORPORATION, Tokyo (JP)

(72) Inventors: Koji OHASHI, Matsumoto-shi (JP); Eiju HIRAI, Nagano-ken (JP)

(73) Assignee: SEIKO EPSON CORPORATION, Tokyo (JP)

(21) Appl. No.: 14/172,956

(22) Filed: Feb. 5, 2014

(30) Foreign Application Priority Data
Mar. 12, 2013 (JP) 2013-048839

(51) Int. Cl. B41J 2/14; H01L 41/053

(52) U.S. Cl. CPC B41J 2/14201; H01L 41/0533
USPC 347/68; 310/340

(57) ABSTRACT

Provided is a piezoelectric element which includes a first electrode, a piezoelectric body layer provided on the first electrode, a second electrode provided on the piezoelectric body layer, and a protection film constituted by a silicon oxide layer that is formed using trimethoxysilane and a liquid-phase zirconia layer, in which the protection film is formed to extend from upper portions of the first electrode and the second electrode to boundary portions between the electrodes and the piezoelectric body layers.

### BACKGROUND

1. Technical Field

The present invention relates to a piezoelectric element, a liquid ejecting head, a liquid ejecting apparatus, an ultrasonic transducer, and an ultrasonic device.

2. Related Art

A liquid ejecting head in which a piezoelectric element is deformed to cause pressure fluctuation of liquid in a pressure generating chamber, and thus liquid droplets are ejected from nozzles communicating with the pressure generating chamber has been known. A representative example of the liquid ejecting head includes an ink-jet type recording head in which ink droplets are ejected as the liquid droplets.

Such an ink-jet type recording head includes, for example, a piezoelectric element on one surface side of a flow-passage forming substrate in which a pressure generating chamber communicating with nozzle openings is provided. This ink-jet type recording head causes ink droplets to be ejected from nozzles in a manner such that a vibrating plate is deformed by driving the piezoelectric element, and thus pressure fluctuation is caused in the pressure generating chamber.

There is a possibility that such a piezoelectric element may be damaged due to the external environment, such as ink or moisture (humidity). Accordingly, a device in which an outer circumferential surface of a piezoelectric element is covered with an insulator-based protection film, and thus the piezoelectric element is prevented from being damaged has been proposed (see JP-A-2005-178293, for example). The protection film is formed of a material, such as aluminum oxide and formed by a CVD method or a sputtering method.

However, in a case in which the protection film is formed on the piezoelectric element by the sputtering method, there is a possibility that damage, such as a crystal defect, may be caused in the piezoelectric element by plasma generated when sputtering is performed. When damage is caused in the piezoelectric element, as described above, the piezoelectric properties of the piezoelectric element are deteriorated.

Furthermore, the performance of an ultrasonic transducer using the piezoelectric element or an ultrasonic device using the ultrasonic transducer is also deteriorated due to a crystal defect or the like. In addition, the ink-discharging performance of an ink-jet type recording head using the piezoelectric element is also deteriorated due to a crystal defect or the like. Similarly, such problems are caused not only in the ink-jet type recording head but also in a liquid ejecting head which ejects liquid apart from ink.

### SUMMARY

An advantage of some aspects of the invention is to provide a piezoelectric element of which the piezoelectric properties are improved by suppressing damage caused when a protection film is formed, a liquid ejecting head which includes the piezoelectric element and has excellent liquid-discharging properties, a liquid ejecting apparatus, and an ultrasonic transducer and ultrasonic device of which the performance are improved.

According to an aspect of the invention, there is provided a piezoelectric element which includes a first electrode, a piezoelectric body layer provided on the first electrode, a second electrode provided on the piezoelectric body layer, and a protection film including a liquid-phase zirconia layer, in which the protection film is formed to extend from an upper portion of either one of the first electrode or the second electrode to a boundary between the electrode and the piezoelectric body layer.

According to the aspect described above, the liquid-phase zirconia layer is provided as a protection film, and thus it is possible to obtain the piezoelectric element of which the piezoelectric properties are improved by suppressing damage. In addition, the protection film is formed up to the boundary described above, and thus it is possible to prevent the leak current from flowing from the first electrode to the second electrode on the surface of the piezoelectric body layer.

In the piezoelectric element, the protection film may cover a boundary between the first electrode and the piezoelectric body layer and a boundary between the second electrode and the piezoelectric body layer and may be formed to extend from the first electrode to the second electrode. According to the configuration described above, the protection film is formed from the first electrode, including the entire side surface of the piezoelectric body layer, to the second electrode. Thus, it is possible to more securely protect the piezoelectric body layer.

In the piezoelectric element, the protection film may include a silicon oxide layer that is formed on the liquid-phase zirconia layer using trimethoxysilane. The silicon oxide layer protects the piezoelectric element from moisture and the liquid-phase zirconia layer causes the protection film to be in close contact securely with the piezoelectric element. In other words, the piezoelectric element which is more securely protected from moisture and in which the protection film is prevented from being separated can be obtained.

According to another aspect of the invention, there is provided a liquid ejecting head including the piezoelectric element of the aspects described above.

According to the aspect described above, the liquid ejecting head having favorable liquid-discharging properties is obtained.

According to still another aspect of the invention, there is provided a liquid ejecting apparatus including the liquid ejecting head of the aspect described above.

According to the aspect described above, the liquid ejecting apparatus having favorable liquid-discharging properties is obtained.

According to still another aspect of the invention, there is provided an ultrasonic transducer including the piezoelectric element of the aspects described above.

According to the aspect described above, the ultrasonic transducer is provided with the piezoelectric element in which a crystal defect is prevented from being caused, and thus the ultrasonic transducer having an improved performance is obtained.

According to still another aspect of the invention, there is provided an ultrasonic device that includes a substrate having an opening, and the ultrasonic transducer of the aspect described above.

According to the aspect described above, the ultrasonic device is provided with the ultrasonic transducer having the piezoelectric element in which a crystal defect is prevented from being caused, and thus the ultrasonic device having an improved performance is obtained.

### BRIEF DESCRIPTION OF THE DRAWINGS

The invention will be described with reference to the accompanying drawings, wherein like numbers reference like elements.

FIG. 1 is a perspective view of an ink-jet type recording head according to embodiment 1.

FIGS. 2A and 2B are a top view and a cross-sectional view of the ink-jet type recording head according to the embodiment 1.

FIGS. 3A and 3B are enlarged cross-sectional views illustrating principal portions of a piezoelectric element according to the embodiment 1.

FIG. 4 is an enlarged cross-sectional view illustrating a principal portion of a piezoelectric element according to a modification example.

FIG. 5 is an enlarged cross-sectional view illustrating a principal portion of a piezoelectric element according to another modification example.

FIG. 6 is an enlarged cross-sectional view illustrating a principal portion of a piezoelectric element according to another modification example.

FIGS. 7A and 7B are enlarged cross-sectional views illustrating principal portions of a piezoelectric element according to embodiment 2.

FIGS. 8A and 8B are a top view and a cross-sectional view of an ultrasonic transducer according to embodiment 3.

FIG. 9 is a schematic view of the ink-jet type recording apparatus.

### DESCRIPTION OF EXEMPLARY EMBODIMENTS

Hereinafter, details of embodiments of the invention will be described with reference to the accompanying drawings. In addition, an ink-jet type recording head is an example of a liquid ejecting head and also simply referred to as a head.

### Embodiment 1

FIG. 1 is a perspective view of a head according to embodiment 1, and FIGS. 2A and 2B are a top view and a cross-sectional view of the head. In addition, a protection substrate 30 is not illustrated in the top view of the head, which is illustrated in FIG. 2.

A head I includes a flow-passage forming substrate 10 and pressure generating chambers 12 are formed in the flow-passage forming substrate 10, as illustrated in the drawings. The pressure generating chambers 12 are partitioned by a plurality of partition walls 11 and arranged in parallel along a direction in which a plurality of nozzle openings 21 through which ink is discharged are arranged in parallel. Hereinafter, this direction is referred to as a parallel arrangement direction of the pressure generating chambers 12 or a first direction X. In addition, in a plane of the flow-passage forming substrate 10, a direction perpendicular to the first direction X is set to be a second direction Y. Furthermore, a direction perpendicular to the first direction X and the second direction Y is set to be a third direction Z. Although, one row of the pressure generating chambers 12 which are arranged in parallel in the first direction X is illustrated in the drawings, a plurality of rows of the pressure generating chambers 12 may be arranged in parallel in the second direction Y.

In one end portion, sides of the respective pressure generating chamber 12 of the flow-passage forming substrate 10 in the second direction Y, ink feeding paths 13 and communication paths 14 are partitioned by the plurality of partition walls 11. In external sides (sides opposite the pressure generating chambers 12 in the second direction Y) of the communication paths 14, communication portions 15 constituting a part of a manifold 100 which functions as a common ink chamber (a liquid chamber) of each pressure generating chamber 12 are formed. In other words, a liquid flow passage constituted by the pressure generating chamber 12, the ink feeding path 13, the communication path 14, and the communication portion 15 is provided in the flow-passage forming substrate 10.

A nozzle plate 20 is joined, by means of an adhesive agent, a thermal bonding film, or the like, to one surface of the flow-passage forming substrate 10, that is, a surface in which the liquid flow passage, such as the pressure generating chamber 12, is open. The nozzle openings 21 that respectively communicate with the pressure generating chambers 12 are bored in the nozzle plate 20.

A vibrating plate 50 is formed on the other surface of the flow-passage forming substrate 10. The vibrating plate 50 according to the embodiment 1 is constituted by an elastic film 51 formed on the flow-passage forming substrate 10 and an insulator film 52 formed on the elastic film 51. In addition, a part of the flow-passage forming substrate 10, which has been processed to be thin, can also be used as an elastic film of the vibrating plate. Furthermore, the liquid flow passage, such as the pressure generating chamber 12, is formed in such a manner that one surface of the flow-passage forming substrate 10 is subjected to anisotropic etching. The other surface of the liquid flow passage, such as the pressure generating chamber 12, is constituted by the vibrating plate 50 (the elastic film 51).

A piezoelectric element 300 that is constituted by a first electrode 60, a piezoelectric body layer 70, a second electrode 80, and a protection film 200 is formed on the vibrating plate 50. In the embodiment 1, the piezoelectric element 300 provided on the flow-passage forming substrate 10 functions as an actuator. Details of the piezoelectric element 300 will be described below.

The protection substrate 30 for protecting the piezoelectric element 300 is joined, by means of an adhesive agent 35, to the upper portion of the flow-passage forming substrate 10, at which the piezoelectric element 300 is formed. A piezoelectric element holding portion 31 that is a concave portion defining a space for accommodating the piezoelectric element 300 is provided in the protection substrate 30. Furthermore, a manifold portion 32 that constitutes a part of the manifold 100 is provided in the protection substrate 30. The manifold portion 32 passes through the protection substrate 30 in a thickness direction and is formed along a width direction of the pressure generating chamber 12. As described above, the manifold portion 32 communicates with the communication portion 15 of the flow-passage forming substrate 10. In addition, a through-hole 33 which passes through the protection substrate 30 in the thickness direction is provided in the protection substrate 30.

The second electrode 80 of each piezoelectric element 300 is connected to a lead electrode 90. Specifically, a through-portion 211 which passes through the protection film 200 in a thickness direction is formed in the protection film 200 of the piezoelectric element 300, and part of the second electrode 80 is exposed through the through-portion 211. The lead electrode 90 is formed on the protection film 200 and connected to the second electrode 80 via the through-portion 211. Furthermore, one end of the lead electrode 90 is exposed to the inside of the through-hole 33. In the through-hole 33, one end of a connection wiring 121 which is connected to a drive circuit 120 is connected to the lead electrode 90.

A compliance substrate 40 constituted by a sealing film 41 and a fixing plate 42 is joined to an upper portion of the protection substrate 30. The sealing film 41 is formed of a flexible material having low rigidity, and one surface of the manifold portion 32 is sealed by the sealing film 41. In addition, the fixing plate 42 is formed of a hard material, such as metal. A part of the fixing plate 42, which is opposite the manifold 100, is completely removed in the thickness direction, and thus forming an opening portion 43. Accordingly, one surface of the manifold 100 is sealed by only the sealing film 41 having flexibility.

In the head I according to the embodiment 1, ink is fed through an ink inlet which is connected to external ink feeding means (not illustrated), and the inner portion of the liquid flow passage from the manifold 100 to the nozzle opening 21 is filled with the ink. Then, voltage is applied, based on a recording signal from the drive circuit 120, between each first electrode 60 and each second electrode 80, which are corresponding to pressure generating chamber 12. As a result, the vibrating plate 50 is flexibly deformed along with the piezoelectric element 300, and thus the inner pressure of each pressure generating chamber 12 increases. Therefore, an ink droplet is ejected through each nozzle opening 21.

Here, details of the piezoelectric element 300 constituting the actuator will be described. FIG. 3A is a cross-sectional view taken along the line IIIA-IIIA in FIG. 2, and FIG. 3B is an enlarged cross-sectional view illustrating principal portions in FIG. 3A.

The first electrode 60 is continuously formed on the vibrating plate 50 so as to correspond to each pressure generating chamber 12 and constitutes a common electrode of the plurality of piezoelectric elements 300, as illustrated in FIGS. 2A to 3B. In the embodiment 1, the first electrode 60 is formed to substantially cover the entirety of each pressure generating chamber 12, as illustrated in the top view of FIG. 2A.

The material forming the first electrode 60 is not particularly limited as long as the material is a metallic material, conductive oxide, or laminate formed thereof. Examples of the material forming the first electrode 60 may include metal, such as Ti, Pt, Ta, Ir, Sr, In, Sn, Au, Al, Fe, Cr, Ni, Cu, conductive oxide represented by lanthanum nickel oxide (LNO) or the like, one of these materials, and a mixture or laminate formed of two or more of these materials.

The piezoelectric body layers 70 are individually formed for each pressure generating chamber 12. The cross-section of the piezoelectric body layer 70 according to the embodiment 1 has a substantially trapezoid shape in which a side surface is inclined (see FIG. 3A). The width of the piezoelectric body layer 70 in the first direction X is slightly smaller than the width of the pressure generating chamber 12. In addition, the width of the piezoelectric body layer 70 in the second direction Y is greater than the width of the pressure generating chamber 12 (see FIG. 2B).

An example of the piezoelectric body layer 70 includes a crystalline film (a perovskite type crystal) which has a perovskite structure and is formed on the first electrode 60. In this case, the crystalline film is formed of ferroelectric ceramics material exhibiting electromechanical transducing action. Examples of material forming the piezoelectric body layer 70 can include a ferroelectric piezoelectric material, such as lead zirconate titanate (PZT), a material obtained by adding metal oxide, such as niobium oxide, nickel oxide, and magnesium oxide to the material mentioned above, and the like. Specifically, lead titanate (PbTiO₃), lead zirconate titanate (Pb(Zr,Ti)O₃), lead zirconium (PbZrO₃), lead lanthanum titanate ((Pb,La),TiO₃), lead lanthanum zirconate titanate ((Pb,La)(Zr,Ti)O₃), magnesium niobate lead zirconium titanate (Pb(Zr,Ti)(Mg,Nb)O₃), or the like can be used. In the embodiment 1, lead zirconate titanate (PZT) is used as the piezoelectric body layer 70.

In addition, the material forming the piezoelectric body layer 70 is not limited to a lead-based piezoelectric material containing lead. A non-lead-based piezoelectric material not containing lead can also be used as the material forming the piezoelectric body layer 70. Examples of the non-lead-based piezoelectric material can include bismuth ferrite ((BiFeO₃), referred to as “BFO” as an abbreviation), barium titanate ((BaTiO₃), referred to as “BT” as an abbreviation), potassium sodium niobate ((K,Na) (NbO₃), referred to as “KNN” as an abbreviation), potassium sodium niobate lithium ((K,Na,Li) (NbO₃)), niobate tantalate potassium sodium lithium (K,Na,Li) (Nb,Ta)O₃), bismuth potassium titanate ((Bi_{1/2}K_{1/2})TiO₃, referred to as “BKT” as an abbreviation), sodium bismuth titanate ((Bi_{1/2}Na_{1/2})TiO₃, referred to as “BNT” as an abbreviation), manganese bismuth (BiMnO₃, referred to as “BM” as an abbreviation), composite oxide (x[(BiₓK₁₋ₓ)TiO₃]-(1-x)[BiFeO₃], referred to as “BKT-BF” as an abbreviation) which contains bismuth, potassium, titanium and iron and has a perovskite structure, composite oxide ((1-x)[(BiFeO₃]-x[BaTiO₃], referred to as “BFO-BT” as an abbreviation) which contains bismuth, iron, barium, and titanium and has a perovskite structure, and a material obtained by adding metal, such as manganese, cobalt, and chromium, to the material mentioned above ((1-x) [(Bi(Fe_{1-y}M_{y})O₃]-x[BaTiO₃] (M is Mn, Co or Cr)).

The second electrodes 80 are provided on upper surfaces of the respective piezoelectric body layers 70 and form an individual electrode for each of the plurality of the piezoelectric elements 300. In the embodiment 1, the width of the second electrode 80 in the first direction X is smaller than the width of the pressure generating chamber 12 (see FIG. 3A). In addition, the width of the second electrode 80 in the second direction Y is greater than the width of the pressure generating chamber 12 (see FIG. 2B). The material forming the second electrode 80 is not particularly limited as long as the material is a metallic material, and the same material as the first electrode 60 can be used.

When voltage is applied between the first electrode 60 and the second electrode 80, a piezoelectric distortion is caused in the piezoelectric body layer 70 which is interposed between the first electrode 60 and the second electrode 80. The deformation of the piezoelectric body layer 70 causes the vibrating plate 50 to be deformed, and thus pressure fluctuation is caused in the pressure generating chamber 12.

The protection film 200 is formed on the laminate of the first electrode 60, the piezoelectric body layer 70, and the second electrode 80.

The protection film 200 includes a liquid-phase zirconia layer 201 and is formed to extend from an upper portion of either one of the first electrode 60 and the second electrode 80 to a boundary between the electrode and the piezoelectric body layer 70. In the embodiment 1, the protection film 200 is constituted by the liquid-phase zirconia layer 201 and a silicon oxide layer 202 laminated on the liquid-phase zirconia layer 201.

A peripheral portion of a joint surface between the piezoelectric body layer 70 and the first electrode 60 is set to be a boundary portion 65 between the first electrode 60 and the piezoelectric body layer 70. In addition, a peripheral portion of a joint surface between the piezoelectric body layer 70 and the second electrode 80 is set to be a boundary portion 85 between the second electrode 80 and the piezoelectric body layer 70.

The protection film 200 is formed to extend from the upper portion of the first electrode 60 to the boundary portion 65 between the first electrode 60 and the piezoelectric body layer 70. In other words, the protection film 200 is formed to cover the boundary portion 65 from the upper portion of the first electrode 60. Furthermore, the protection film 200 is formed to extend from the upper portion of the second electrode 80 to the boundary portion 85 between the second electrode 80 and the piezoelectric body layer 70. In other words, the protection film 200 is formed to cover the boundary portion 85 from the upper portion of the second electrode 80.

The protection film 200 according to the embodiment 1 is formed over the entirety of, including the boundary portion 65 and the boundary portion 85, side surfaces of the piezoelectric body layer 70, the first electrode 60 (except a joint portion to the lead electrode 90), and the second electrode 80. In addition, an opening portion 210 which is formed by partially removing the protection film 200 on the second electrode 80 is formed in the protection film 200. A part of the protection film 200 is removed as described above, and thus the displacement of the piezoelectric element 300 is prevented from being excessively obstructed by the protection film 200.

The protection film 200 is formed to substantially cover the entirety of the first electrode 60, the second electrode 80, and the piezoelectric body layer 70, as described above, and thus the piezoelectric body layer 70 is prevented from absorbing moisture. In other words, the protection film 200 can prevent the piezoelectric body layer 70 from causing a dielectric breakdown owing to moisture.

Furthermore, the protection film 200 is formed over the entire side surface of the piezoelectric body layer 70 and particularly is formed to extend from the first electrode 60 to the boundary portion 65 and from the second electrode 80 to the boundary portion 85. Thus, in the side surface of the piezoelectric body layer 70, current is prevented from leaking between the first electrode 60 and the second electrode 80. In other words, the protection film 200 can prevent the piezoelectric element 300 from being damaged due to the leak current which flows along the side surface of the piezoelectric element 300.

In addition, the liquid-phase zirconia layer 201 constituting the protection film 200 is formed of zirconia which is formed by a liquid phase method. The liquid-phase zirconia layer 201 is formed as follows. Metal alkoxide containing zirconia or precursor solution containing metal carboxylate, for example, is applied to the flow-passage forming substrate 10 which includes the first electrode 60, the piezoelectric body layer 70, and the second electrode 80. Then, the applied material is subjected to a drying process, a degreasing process, a pre-calcination process, and a main calcination process.

The liquid-phase zirconia layer 201 is formed by a liquid phase method mentioned above. Thus, upon comparison with a case where the protection film is formed by a dry process, such as a sputtering method, less damage is caused to the first electrode 60, the piezoelectric body layer 70, and the second electrode 80 by forming the liquid-phase zirconia layer 201. Therefore, damage on the piezoelectric element 300 is reduced when forming the protection film 200, and thus piezoelectric properties are prevented from deteriorating.

In addition, the liquid-phase zirconia layer 201 can repair the damage caused when the piezoelectric body layer 70 is formed.

Specifically, when the first electrode 60 is formed, and then the piezoelectric body layers 70 are patterned for each pressure generating chamber 12 by a dry etching, damage can be caused to the piezoelectric body layer 70 by the dry etching. Generally, the piezoelectric body layer 70 is subjected to an annealing treatment after the piezoelectric body layer 70 is formed, and thus the damage thereon is repaired.

However, without having to implement the annealing treatment, the damage on the piezoelectric body layer 70 can be repaired by the calcination process performed when forming the liquid-phase zirconia layer 201. Since, the damage on the piezoelectric body layer 70 is repaired when the liquid-phase zirconia layer 201 is formed, as described above, it is possible to obtain the piezoelectric element 300 having more excellent piezoelectric properties.

In addition, the liquid-phase zirconia layer 201 has excellent adhesive properties with respect to other layers laminated thereon. In the embodiment 1, the liquid-phase zirconia layer 201 has excellent adhesive properties with respect to the first electrode 60, the piezoelectric body layer 70, the second electrode 80, and the silicon oxide layer 202.

Therefore, a layer which is formed of a material having excellent properties protecting the first electrode 60, the piezoelectric body layer 70, and the second electrode 80 from moisture (hydrogen) is formed on the liquid-phase zirconia layer 201 to constitute the protection film 200. This layer allows the protection film 200 to be successfully in close contact with the first electrode 60, the piezoelectric body layer 70, and the second electrode 80.

In the embodiment 1, the silicon oxide layer 202 is provided on the liquid-phase zirconia layer 201. The silicon oxide layer 202 of the embodiment 1 is formed of oxide silicon which is formed using trimethoxysilane (TMS). The silicon oxide layer 202 is formed by a chemical vapor deposition (CVD) method, for example.

The silicon oxide layer 202 has excellent anti-moisture properties comparable to a protection film formed of alumina or Diamond-Like Carbon (DLC), which are used in the related art. Furthermore, Young's modulus of the silicon oxide layer 202 is smaller than Young's modulus of the protection film of the related art, and thus it is difficult for the silicon oxide layer 202 to obstruct the displacement of the piezoelectric element 300. In other words, the displacement amount of the piezoelectric element 300 is improved, compared to the case in which the protection film of the related art is used. Meanwhile, the silicon oxide layer 202 has inferior adhesive properties with respect to metal, such as the first electrode 60.

However, the silicon oxide layer 202 is securely in close contact with the first electrode 60, the piezoelectric body layer 70, and the second electrode 80, via the liquid-phase zirconia layer 201. Describing in terms of the entire protection film 200, the silicon oxide layer 202 protects the piezoelectric element 300 from moisture and the liquid-phase zirconia layer 201 causes the protection film 200 to be securely in close contact with the piezoelectric element 300, as described above.

In the piezoelectric element 300 provided with the protection film 200, the protection film 200 is prevented from being separated and securely protected from moisture. In addition, the displacement amount of the piezoelectric element 300 increases, compared to a piezoelectric element using the protection film of the related art.

Furthermore, the head I which includes the piezoelectric element 300 according to the embodiment 1 has excellent ink-discharge properties because of the piezoelectric element 300 having improved piezoelectric properties.

Here, other aspects of the protection film 200 of the piezoelectric element 300 will be described. FIGS. 4 to 6 are enlarged cross-sectional views illustrating principal portions of the piezoelectric element.

The protection film 200 may be formed from the upper portion of the second electrode 80 to the boundary portion 85 and may not be formed from the upper portion of the first electrode 60 to the boundary portion 65, as illustrated in FIG. 4. Even in the case of the protection film 200 having such aspects, it is possible to prevent the piezoelectric body layer 70 from receiving damage because the protection film 200, that is, the liquid-phase zirconia layer 201, is formed in a liquid phase. In addition, the protection film 200 covers the boundary portion 85. Thus, in the surface of the piezoelectric body layer 70, it is possible to prevent the leak current from occurring between the first electrode 60 and the second electrode 80.

The protection film 200 may be formed from the upper portion of the first electrode 60 to the boundary portion 65 and may not be formed from the upper portion of the second electrode 80 to the boundary portion 85, as illustrated in FIG. 5. Even in the case of the protection film 200 having such aspects, it is possible to prevent the piezoelectric body layer 70 from receiving damage because the protection film 200, that is, the liquid-phase zirconia layer 201, is formed in a liquid phase. In addition, the protection film 200 covers the boundary portion 65. Thus, in the surface of the piezoelectric body layer 70, it is possible to prevent the leak current from occurring between the first electrode 60 and the second electrode 80.

The protection film 200 may be formed at least from the upper portion of the first electrode 60 to the boundary portion 65 and from the upper portion of the second electrode 80 to the boundary portion 85, as illustrated in FIG. 6. In other words, a part of the side surface of the piezoelectric body layer 70 may be exposed.

Even in the case of the protection film 200 having such aspects, it is possible to prevent the piezoelectric body layer 70 from receiving damage because the protection film 200, that is, the liquid-phase zirconia layer 201, is formed in a liquid phase. In addition, the protection film 200 covers the boundary portion 65 and the boundary portion 85. Thus, in the surface of the piezoelectric body layer 70, it is possible to prevent the leak current from occurring between the first electrode 60 and the second electrode 80.

Incidentally, although not particularly illustrated, the protection film 200 may be constituted by only the liquid-phase zirconia layer 201. In this case, the liquid-phase zirconia layer 201 protects the piezoelectric element 300 from moisture. Furthermore, in the embodiment 1 described above, the silicon oxide layer 202 which is formed using TMS is formed on the liquid-phase zirconia layer 201. However, without being limited thereto, the protection film 200 may be formed of any material as long as the material can protect the piezoelectric element 300 from moisture. Alumina or DLC may be laminated on the liquid-phase zirconia layer 201, for example. In addition, the number of layers formed on the liquid-phase zirconia layer 201 is not limited to one and may be two or more.

### Embodiment 2

In the description of the embodiment 1, a case in which the protection film 200 is formed on the piezoelectric element 300 of which the first electrode 60 is a common electrode and the second electrodes 80 are individual electrodes is exemplified. In the description of embodiment 2, a case in which a protection film 200A is formed on the piezoelectric element 300 of which the first electrode 60 is an individual electrode and the second electrodes 80 is a common electrode will be exemplified.

FIGS. 7A and 7B are a cross-sectional view of the head according to the embodiment 2 and an enlarged cross-sectional view illustrating principal portions thereof. In addition, the same reference numerals are given to the same members as those in the embodiment 1, and the same descriptions will not be repeated.

The first electrodes 60 constituting the piezoelectric element 300 are separated for each pressure generating chamber 12 and constitutes an individual electrode separated for each piezoelectric element 300. Although not particularly illustrated, the width of the first electrode 60 in the first direction X of the pressure generating chamber 12 is smaller than the width of the pressure generating chamber 12. In addition, both end portions of the first electrode 60 in the second direction Y of the pressure generating chamber 12 extend to the outside of the pressure generating chamber 12, as illustrated in FIG. 7B.

The piezoelectric body layer 70 is formed to continuously extend in the first direction X and has a predetermined width in the second direction Y. The width of the piezoelectric body layer 70 in the second direction Y is greater than the width of the pressure generating chamber 12 in the second direction Y. In addition, although not particularly illustrated, a part of the piezoelectric body layer 70, which is opposite the partition wall 11, is removed to form a concave portion.

An end portion of the piezoelectric body layer 70, which is located on one end side (an ink feeding path 13 side in the embodiment 2) of the pressure generating chamber 12 in the second direction Y, is positioned further outside than an end portion of the first electrode 60. In other words, the end portion of the first electrode 60 is covered with the piezoelectric body layer 70. An end portion of the piezoelectric body layer 70, which is located on the other end side of the pressure generating chamber 12 in the second direction Y, is positioned further inside (a pressure generating chamber 12 side) than the end portion of the first electrode 60.

The second electrode 80 is continuously formed on the piezoelectric body layer 70 in the first direction X of the pressure generating chamber 12 and constitutes a common electrode of the plurality of piezoelectric elements 300.

An end portion of the second electrode 80, which is located on one end side of the pressure generating chamber 12 in the second direction Y, is positioned further outside than the end portion of the piezoelectric body layer 70. In other words, the end portion of the piezoelectric body layer 70 is covered with the second electrode 80. In addition, an end portion of the second electrode 80, which is located on the other end side of the pressure generating chamber 12 in the second direction Y, is positioned further inside (a pressure generating chamber 12 side) than the end portion of the piezoelectric body layer 70.

Through-portions 212 which are formed by partially removing the piezoelectric body layers 70 are formed on the respective piezoelectric body layer 70 for each piezoelectric element 300. The first electrode 60 of each piezoelectric element 300 is exposed through the through-portion 212, and the lead electrode 90 is connected to the first electrode 60 through the through-portion 212.

As similar to the piezoelectric element 300 according to the embodiment 1, when voltage is applied between the first electrode 60 and the second electrode 80 of the piezoelectric element 300 according to the embodiment 2, a piezoelectric distortion is caused in the piezoelectric body layer 70 which is interposed between the first electrode 60 and the second electrode 80. A part of the piezoelectric body layer 70, which is piezoelectrically distorted when the voltage is applied to both electrodes, is set to be an active portion 320. In contrast, a part of the piezoelectric body layer 70, which is not piezoelectrically distorted, is set to be a non-active portion. Furthermore, in the active portion 320 of the piezoelectric body layer 70, which is piezoelectrically distorted, a part opposite the pressure generating chamber 12 is set to be a flexible portion and a part located outside the pressure generating chamber 12 is set to be a non-flexible portion.

In the embodiment 2, the first electrode 60 and the piezoelectric body layer 70 continuously extend to the outside of the pressure generating chamber 12 in the second direction Y of the pressure generating chamber 12, and the second electrode 80 extends to the inside of the pressure generating chamber 12. In other words, the active portion 320 is located inside the pressure generating chamber 12. Therefore, stress due to the deformation of the piezoelectric element 300 is concentrated on an end portion of the active portion 320, that is, the boundary portion 85 between the second electrode 80 and the piezoelectric body layer 70.

The protection film 200A according to the embodiment 2 is formed to extend from the upper portion of the second electrode 80 to the boundary portion 85. Furthermore, the protection film 200A covers the surface of the piezoelectric body layer 70 to the lead electrode 90. The protection film 200A is formed of a liquid-phase zirconia and has the same operational effects as those of the embodiment 1.

Furthermore, the liquid-phase zirconia has excellent adhesive properties, and thus it is possible for the liquid-phase zirconia to reinforce the boundary portion 85 on which the stress is concentrated. There is a possibility that the stress may be concentrated on the boundary portion 85, and thus the second electrode 80 is separated from the piezoelectric body layer 70 and damaged. However, the protection film 200A having favorable adhesive properties reinforces the boundary portion 85, and thus it is possible to prevent the second electrode 80 from being separated from the piezoelectric body layer 70.

As described above, the piezoelectric element 300 provided with the protection film 200A is reliable in that the piezoelectric element 300 is prevented from being damaged due to the stress which is caused by the deformation.

### Embodiment 3

An ultrasonic transducer which is an embodiment of the invention and an ultrasonic device equipped with the ultrasonic transducer will be described. In addition, an embodiment described below is not intended to limit the contents of the invention, which are described in the claims. Also, it is difficult to say that all of the components described in the embodiment are essential as solving means of the invention. In addition, the same reference numerals are given to the same members as those in the embodiment 1 described above, and the same descriptions will not be repeated.

In embodiment 3, transmission and reception of ultrasonic waves are performed by an electroacoustic transducer using a piezoelectric effect. The electroacoustic transducer is a piezoelectric element. When transmitting the ultrasonic waves, the piezoelectric element uses the conversion (an inverse piezoelectric effect) of electric energy into mechanical energy. The change caused by contraction and extension of the piezoelectric body layer emits ultrasonic waves by exciting the vibrating plate to oscillate. Accordingly, in this case, it is possible to say that the piezoelectric element functions as an ultrasonic transducer for transmission.

Furthermore, when receiving the ultrasonic waves reflected from a detection target, the piezoelectric element uses the conversion (a normal piezoelectric effect) of mechanical energy into electric energy. Thus, the deformation of the piezoelectric body layer generates electric energy, and the electric energy signals are detected to form an image. Accordingly, in this case, it is possible to say that the piezoelectric element functions as an ultrasonic transducer for reception.

Furthermore, the piezoelectric element of the embodiment 3 includes a vibrating plate, a first electrode provided on the vibrating plate, a piezoelectric body layer provided on the first electrode, and a second electrode provided on the piezoelectric body layer.

FIG. 8A is a top view of an ultrasonic device equipped with the ultrasonic transducer according to the embodiment 3, and FIG. 8B is a cross-sectional view thereof taken along the line VIIIB-VIIIB.

As illustrated in FIG. 8A, the plurality of ultrasonic transducers for transmission 301 and ultrasonic transducers for reception 302 are arrayed on the substrate 10 having the opening portions 12A and form an ultrasonic device 400 (an array sensor). The plurality of ultrasonic transducers for transmission 301 and the plurality of ultrasonic transducers for reception 302 are alternately disposed for every one column, and electric conduction is switched for each column of the ultrasonic transducers. Line scanning and sector scanning are conducted in accordance with the switch of the electric conduction. In addition, output and input levels of the ultrasonic waves are determined in accordance with the number of rows and columns of the ultrasonic transducers which are electrically conducted. A configuration of 6×6 is illustrated in FIG. 8A. The number of rows and columns of this arrangement can be determined in accordance to the range of scanning.

Furthermore, the ultrasonic transducers for transmission 301 and the ultrasonic transducers for reception 302 can also be alternately arranged not for each column but for each ultrasonic transducer. In this case, the ultrasonic-wave transmitting and receiving source is configured so that the central axes of the transmitting side and the receiving side thereof are in alignment, and thus directional angles between the transmitting and the receiving are easily aligned.

Furthermore, to reduce the size of the ultrasonic device, both the ultrasonic transducers for transmission 301 and the ultrasonic transducers for reception 302 of the embodiment 3 are disposed on one substrate 10. However, the ultrasonic transducers for transmission 301 and the ultrasonic transducers for reception 302 can also be respectively disposed, considering the function of the ultrasonic transducer, on separate substrates or a plurality of substrates can be used in accordance with the application. Incidentally, one ultrasonic transducer can have both transmitting and receiving functions using the time difference between the transmitting and receiving.

In the case of being illustrated in FIG. 8B, an example applicable to an ultrasonic-wave transducer includes a substrate 10A which is formed of a single crystal silicon having a (100), a (110), or a (111) orientation. Furthermore, examples of the material forming the substrate 10A may include, in addition to a silicon material, a ceramic material represented by ZrO₂ or Al₂O₃, a glass-ceramic material, an oxide substrate material, such as MgO, LaAlO₃, an inorganic material, such as SiC, SiO₂, a polycrystalline silicon, and Si₃N₄. In addition, a laminated material using a combination of these materials may also be used.

The vibrating plate 50 is formed on an upper side (a piezoelectric body layer 70 side) of the substrate 10A. The vibrating plate 50 may be constituted by a partially thinned substrate 10A. Also, the piezoelectric body layer 70 or the first electrode 60 may also be used as the vibrating plate 50. Furthermore, the vibrating plate 50 may be constituted by a film formed of other materials. In this case, a silicon compound, such as SiO₂, SiC, Si₃N₄, a polycrystalline silicon, a ceramic material, such as ZrO₂, Al₂O₃, and oxide, such as MgO, LaAlO₃, TiO₂ may be used, for example. The thickness and the material of a film are selected based on the resonance frequency. In addition, it is preferable that the surface layer of the vibrating plate 50 on the piezoelectric body layer 70 side be formed of a material, such as ZrO₂, capable of preventing the diffusion of the material forming the piezoelectric body layer. In this case, the piezoelectric properties of the piezoelectric body layer are improved, and thus this leads to the improvement in the transmission and reception properties of the ultrasonic transducer.

Opening portions 12A are formed in the substrate 10A. The opening portions 12A can be formed by using a processing method matching with a substrate material, such as etching, polishing, or laser processing.

The configurations of the piezoelectric element 300, that is, the configurations of the first electrode 60, the piezoelectric body layer 70, the second electrode 80, and the protection film 200 are the same as those in the embodiment 1 described above, and thus the described thereof will not be repeated. In addition, it is necessary that the driving frequency range of the ultrasonic device is higher than that of a liquid ejecting head which is represented by the ink-jet type recording head I of the embodiment 1 or the like. Therefore, physical properties, such as a thickness and Young's modulus of each electrode material of the piezoelectric body layer 70 and the vibrating plate 50 may be adjusted.

Furthermore, wirings (not illustrated) are respectively connected to the ultrasonic transducer for transmission 301 and the ultrasonic transducer for reception 302, and each wiring is connected to a terminal (not illustrated) of a control substrate (not illustrated) via a flexible printed wiring substrate (not illustrated). A control portion (not illustrated) constituted by an arithmetic logical unit, a storage unit, and the like is provided in the control substrate. The control portion controls input signals input to the ultrasonic transducer for transmission 301 and processes output signals output from the ultrasonic transducer for reception 302.

Upon comparison with a sensor using bulk-type piezoelectric ceramics, in the case of the ultrasonic device of this application, it is possible to arrange, with a narrow pitch (high resolution), the piezoelectric elements 300 manufactured by using a piece of MEMS technology, as described above. Furthermore, the driving voltage is low. Thus, it is effective for a reduction in size, thickness, and power consumption of the ultrasonic device and a device equipped with the ultrasonic device. In addition, manufacturing variations of the piezoelectric elements 300 are reduced, and thus recognition accuracy is improved.

Furthermore, displacement characteristic is improved by reducing the film thickness of the piezoelectric body layer 70, and thus the transmission and reception efficiency of the ultrasonic waves can be improved.

In addition, it is possible to apply any one of the configurations described in the embodiment 1 and embodiment 2 to the ultrasonic transducer 300 constituting the ultrasonic device of the embodiment 3. Thus, even when any piezoelectric element 300 according to the embodiments described above is applied, the ultrasonic transducer of which the piezoelectric properties are improved by reducing damage can be provided. Furthermore, in the protection film 200, the leak current flowing from the first electrode 60 to the second electrode 80 is prevented on the surface of the piezoelectric body layer, and thus the ultrasonic transducer which improved reliability is provided.

### Other Embodiment

Hereinbefore, embodiments of the invention are described. However, a fundamental configuration of the invention is not limited thereto.

For example, the head I is mounted in an ink-jet type recording apparatus II, as illustrated in FIG. 9. The ink-jet type recording apparatus II includes an apparatus main body 4, and a carriage shaft 5 is installed in the apparatus main body 4. A carriage 3 is axially-movably installed on the carriage shaft 5. A cartridge 2 constituting ink feeding means is detachably installed on the carriage 3, and the head I is mounted in the carriage 3.

In addition, a driving force from a driving motor 6 passes through a plurality of gears (not illustrated) and a timing belt 7 and is transmitted to the carriage 3, and thus the carriage 3 in which the head I is mounted moves along the carriage shaft 5. Meanwhile, a platen 8 is installed in the apparatus main body 4 to be placed along the carriage shaft 5. A recording sheet S which is a recording medium, such as a paper sheet, and which is fed by a paper feeding roller (not illustrated) or the like is wound around the platen 8 and transmitted.

In the case of this invention, ink discharging is performed, with superior discharging properties, by using the head I including the piezoelectric element 300 having superior piezoelectric properties. As a result, it is possible to obtain the ink-jet type recording apparatus II having an improved printing quality.

Although, in the example described above, an apparatus in which the head I is mounted in the carriage 3 and moves in a main scanning direction is exemplified as the ink-jet type recording apparatus II, the configuration is not particularly limited thereto. The ink-jet type recording apparatus II may be a so-called line-type recording apparatus in which printing is performed in a state where the head I is fixed and the recording sheet S, such as a paper sheet, moves in a sub-scanning direction, for example.

In the embodiments described above, the invention is described with reference to the ink-jet type recording head as an example of the liquid ejecting head. However, the invention is intended to be applied, widely, to a general liquid ejecting head. Examples of the liquid ejecting head include, in addition to various types of recording heads which are applied to an image recording apparatus, such as a printer, a color-material ejecting head which is used for manufacturing a color filter, such as a liquid crystal display, an electrode-material ejecting head which is used for forming an electrode of an organic EL display, a field emission display (FED), or the like, and a bioorganic material ejecting head which is used for manufacturing a biochip.

The piezoelectric element according to the invention can be applied not only to the liquid ejecting head (the ink-jet type recording head) or the ultrasonic device described above but also to an actuator mounted in various devices or various types of sensors using a piezoelectric element.

The entire disclosure of Japanese Patent Application No. 2013-048839, filed Mar. 12, 2013 is expressly incorporated by reference herein.

What is claimed is:

1. A piezoelectric element comprising:
a first electrode;
a piezoelectric body layer provided on the first electrode;
a second electrode provided on the piezoelectric body layer; and
a protection film including a liquid-phase zirconia layer,
wherein the protection film is formed to extend from an upper portion of either one of the first electrode or the second electrode to a boundary between the electrode and the piezoelectric body layer.

2. The piezoelectric element according to claim 1,
wherein the protection film covers a boundary between the first electrode and the piezoelectric body layer and a boundary between the second electrode and the piezoelectric body layer and is formed to extend from the first electrode to the second electrode.

3. The piezoelectric element according to claim 1,
wherein the protection film includes a silicon oxide layer that is formed on the liquid-phase zirconia layer using trimethoxysilane.

4. A liquid ejecting head comprising the piezoelectric element according to claim 1.

5. A liquid ejecting head comprising the piezoelectric element according to claim 2.

6. A liquid ejecting head comprising the piezoelectric element according to claim 3.

7. A liquid ejecting apparatus comprising the liquid ejecting head according to claim 4.

8. A liquid ejecting apparatus comprising the liquid ejecting head according to claim 5.

9. A liquid ejecting apparatus comprising the liquid ejecting head according to claim 6.

10. An ultrasonic transducer comprising the piezoelectric element according to claim 1.

11. An ultrasonic transducer comprising the piezoelectric element according to claim 2.

12. An ultrasonic transducer comprising the piezoelectric element according to claim 3.

13. An ultrasonic device comprising:
a substrate having an opening; and
the ultrasonic transducer according to claim 10, which is provided on the substrate.

14. An ultrasonic device comprising:
a substrate having an opening; and
the ultrasonic transducer according to claim 11, which is provided on the substrate.

15. An ultrasonic device comprising:
a substrate having an opening; and
the ultrasonic transducer according to claim 12, which is provided on the substrate.
